(19) United States
(12) Patent Application Publication
(10) Pub. No.: US 2026/0321527 A1
(43) Pub. Date: Oct. 15, 2026

(54) CONTROLLING AN ELECTROMECHANICAL SWITCH AND A SEMICONDUCTOR SWITCH

(71) Applicant: dSPACE SE & Co. KG, Paderborn (DE)

(72) Inventor: Paul GRUBER, Paderborn (DE)

(73) Assignee: dSPACE SE & Co. KG, Paderborn (DE)

(21) Appl. No.: 19/700,732

(22) Filed: Jun. 8, 2026

Related U.S. Application Data
(63) Continuation of application No. PCT/EP2024/084411, filed on Dec. 3, 2024.

(30) Foreign Application Priority Data
Dec. 8, 2023 (DE) 10 2023 134 441.2

(51) Int. Cl. H01H 9/54; H01H 47/00; H03K 17/284

(52) U.S. Cl. CPC H01H 9/547; H01H 9/548; H01H 47/002; H03K 17/284

(57) ABSTRACT

An electromechanical switch, a semiconductor switch, and a control device, whereby the electromechanical switch and the semiconductor switch can be switched on and off. The electromechanical switch and the semiconductor switch are each closed in the switched-on state and are each open in the switched-off state. The electromechanical switch has switching contacts that can be electromechanically connected to one another for switching on and off. The electromechanical switch and the semiconductor switch are connected to one another in series in a load path and both are connected to the control device for switching on and off. The control device is configured such that, when switching off the electromechanical switch and the semiconductor switch to open the load path, it first sends a switch-off signal to the electromechanical switch and then, after a predetermined switch-off delay, sends a switch-off signal to the semiconductor switch.

This nonprovisional application is a continuation of International Application No. PCT/EP2024/084411, which was filed on Dec. 3, 2024, and which claims priority to German Patent Application No. 10 2023 134 441.2, which was filed in Germany on Dec. 8, 2023, and which are both herein incorporated by reference.

### BACKGROUND OF THE INVENTION

### Field of the Invention

The invention relates to an arrangement having an electromechanical switch, a semiconductor switch, and a control device, wherein the electromechanical switch and the semiconductor switch can be switched on and off, wherein the electromechanical switch and the semiconductor switch are each closed in the switched-on state and are each open in the switched-off state, the electromechanical switch has switching contacts that can be electromechanically connected to one another for switching on and off, and the electromechanical switch and the semiconductor switch are connected to one another in series in a load path, and both are connected to the control device for switching on and off. The invention additionally relates to a method for controlling an electromechanical switch and a semiconductor switch, wherein the electromechanical switch has switching contacts that can be electromechanically connected to one another for switching on and off, and the electromechanical switch and the semiconductor switch are connected to one another in series in a load path, and electromechanical switches and the semiconductor switch are connected to the control device for switching on and off.

### Description of Background Art

From the prior art, so-called HIL simulators are known that are used, in particular, for testing control units (“HIL” comes from “Hardware in the Loop”). HIL simulators each include at least one computing unit, wherein the computing unit or computing units have the task, in particular, of executing models that at least partially emulate an environment of an electronic device or of a more complex technical system.

HIL simulators thus make possible a testing method in which an embedded system, in particular an electronic control unit (ECU) or a mechatronic module, is connected through its inputs and outputs to a matched counterpart, namely the HIL simulator, which serves to emulate the real environment of the embedded system. Within the framework of an HIL simulation, the embedded system is also referred to as a device under test (DUT). During the test of the embedded system, therefore, at least some of the input signals for the embedded system are provided by the HIL simulator and at least some of the output signals of the embedded system are sent to the HIL simulator.

An ECU, in particular for a vehicle, is described in, for example, U.S. Pat. Nos. 9,791,884 or 9,593,521, which are both herein incorporated by reference.

For example, the behavior over time of the environment of the system under test can be emulated by means of an environment model that is executed on an HIL simulator. If, for example, an HIL simulator is supposed to test an embedded system, in particular a control unit, then the HIL simulator is designed as an at least partial emulation of the real environment of the control unit. Through its inputs and outputs equipped with a bus interface or network interface, or bidirectional communication channels, the HIL simulator can thus communicate with the control unit in this case and consequently function as a matched counterpart of the control unit.

The HIL simulation is always just a simplification of reality, and therefore cannot replace testing on the real system. If overly great discrepancies between an HIL test and reality occur, the underlying models in the simulation often are simplified too much. The simulation models must then be developed further.

Failure simulations for testing the response of the control unit in failure situations are an essential part of HIL tests. Additional plug-in boards for HIL systems or external devices that, for example, can also be connected to the HIL systems through bus interfaces or network interfaces, so-called failure insertion units (FIUs), also referred to as fault insertion units, are customarily available for the purpose of simulating cable breaks or similar failures. They include circuits with remotely and automatically controllable switches for the simulation of, e.g., cable breaks, short circuits, and/or a so-called contact bounce (bouncing as part of the above-mentioned failures, “intermittent contact”) that can lead to unwanted modulation. There are FIUs for both sensors and actuators, wherein, for actuators, they are additionally combined with load devices. By means of the FIUs, it is thus possible to generate simulation signals that, in particular, represent abnormal, which is to say faulty, operating states. Consequently, an electrical component can be tested not only with regard to normal operation, but also with regard to various failure and/or error states.

In DE 10 2009 048 981 A1, which corresponds to US 2011/0087477, which is incorporated herein by reference, an FIU is described in the form of a device for testing an electronic component, having a simulation device for generating a simulation signal, a testing device for attaching the electronic component, two connecting devices, and a selection device for selecting the connecting device, wherein the simulation device and the testing device can be connected in an electrically conductive manner to one of the connecting devices by means of the selection device, and the individual connecting devices differ from one another with regard to at least one electrical property in each case. Here, the simulation device is designed such that simulation signals can be generated for different operating states of the electronic component and, in particular, simulation signals for faulty operating states of the electronic component can be provided by means of an FIU.

With such an FIU, the signal lines are typically connected to the ground potential or to the positive potential line, which is to say to 0 V or to up to +60 V so that an appropriate voltage can be applied to a device under test. Semiconductor switches, such as MOSFET switches, can, for example, be provided for this application of voltage, but they should be protected in the event of possible overloads. The load path can also be interrupted in order to simulate a cable break.

### SUMMARY OF THE INVENTION

It is therefore an object of the present invention to advance the state of the art. Preferably, the switching of relatively high currents should be enabled at DC voltages that would lead to sustained arcing in a conventional relay during switch-off.

According to an example of the invention, an arrangement having an electromechanical switch, a semiconductor switch, and a control device/ECU, e.g. controller, is therefore provided. The electromechanical switch and the semiconductor switch can be switched on and off, wherein the electromechanical switch and the semiconductor switch are each closed in the switched-on state and are each open in the switched-off state. The electromechanical switch can have switching contacts that can be electromechanically connected to one another for switching on and off. The electromechanical switch and the semiconductor switch can be connected to one another in series in a load path, and electromechanical switches and the semiconductor switch are connected to the control device for switching on and off. Also, the control device can be configured such that, when switching off the electromechanical switch and the semiconductor switch to open the load path, it first sends a switch-off signal to the electromechanical switch and then, after a predetermined switch-off delay, sends a switch-off signal to the semiconductor switch.

Such an arrangement can be used together with an electronic fuse in order to open the electronic switch when there is an overload.

The last-mentioned series connection of electromechanical switches and semiconductor switches in the load path produces an advantage as compared with a circuit or series connection having exclusively one semiconductor switch or exclusively multiple semiconductor switches in the load path. The advantage resides in the avoidance of a disadvantage caused by the intrinsic electrical capacitance that is present between the working contacts (e.g., between source and drain) in a semiconductor switch and is markedly higher, in comparison, in the switched-off state of the semiconductor switch. An electromechanical switch in the series connection with the semiconductor switch avoids the unwanted action of the last-mentioned electrical capacitance. Otherwise, which is to say without the use of an electromechanical switch in the load path, the intrinsic capacitance of the semiconductor switch can, in particular, impair or prevent a realistic emulation (HIL simulation) of a signal interruption in FIU applications.

Fundamentally different approaches come into consideration for the switch-off delay. According to an example of the invention, however, the switch-off delay is chosen such that it leads to a time-limited arc between the switching contacts of the electromechanical switch. This arc serves to clean the switching contacts of the electromechanical switch.

Preferably, it is furthermore the case that the electromechanical switch can have an intrinsic switching time for switching off that is defined by the period between the receiving of the switch-off signal from the control device and the opening of the electromechanical switch, and the switch-off delay is greater than the intrinsic switching time of the electromechanical switch. Preferably, in the present case an electromechanical switch is used of a type that is suitable for 50 Hz/ 250 volt AC applications as well as for DC applications. The maximum arc duration preferably is chosen to be shorter than the duration of a line half-wave of 10 ms. Preferably, the switch-off delay is chosen such that the arc between the switching contacts of the electromechanical switch occurs for a maximum of 7 ms.

The electromechanical switch may have neither a structural design nor a function for suppressing arcs.

With regard to switch-on, it is preferably the case that the control device can be configured such that it sends a respective switch-on signal simultaneously to the electromechanical switch and to the semiconductor switch when switching on the electromechanical switch and the semiconductor switch. In this context, it is, however, the case that the simultaneous switch-on signals generally do not have the result that the semiconductor switch and the electromechanical switch are actually also closed simultaneously, on account of the physical differences between a semiconductor switch on the one hand and an electromechanical switch on the other hand. Instead, the simultaneous switch-on signals generally have the result that the semiconductor switch is closed before the electromechanical switch, which is to say that the semiconductor switch provides an electrically conductive connection before the electromechanical switch.

Preferably, the semiconductor switch can be a MOSFET switch. This switch can be designed to switch one technical direction of current, or preferably to switch both technical directions of current. Moreover, it is preferred that the electromechanical switch is a relay or a contactor.

The semiconductor switch can be used for just one electromechanical switch. According to a preferred improvement of the invention, however, the semiconductor switch is connected in series ahead of a multiplicity of electromechanical switches that are connected in parallel with one another, all of which are connected to the control device for switch-on and switch-off, wherein the control device is configured such that only one of the electromechanical switches can be switched on at the same time.

The invention additionally relates to a failure insertion unit for connection to an HIL simulator through a load path and for emulation of at least one electrical failure and transmission of the same to the HIL simulator through the load path, wherein the load path is equipped with an above-described arrangement. Preferably, the electrical failure is chosen from the group comprising a short circuit of a control unit output to ground potential, a short circuit of a control unit output to supply potential, and a short circuit of a control unit output having a first signal line to a second signal line, as well as a breaking of a signal line that electrically connects a control unit output to a signal sink or connects a control unit input to a signal source. Very especially preferably, the failure insertion unit FIU can provide multiple failures.

The aforementioned short circuits represent failure cases that are brought about for simulation purposes, namely failure cases that are triggered under computer program control. Preferably, the failure insertion unit is connected to a real control unit, more precisely to its real control unit outputs. When an actual control unit is unavailable, resorting to a simulated control unit with simulated control unit outputs is preferred. According to a preferred improvement of the invention, hybrid forms are also used, namely in such a manner that actual control units are connected together in a network with simulated control units, and selected actual and/or simulated control unit outputs are connected to the failure insertion unit.

The invention further resides in a method for controlling an electromechanical switch and a semiconductor switch. The electromechanical switch and the semiconductor switch can be switched on and off, wherein the electromechanical switch and the semiconductor switch are each closed in the switched-on state and are each open in the switched-off state. The electromechanical switch can have switching contacts that can be electromechanically connected to one another for switching on and off. The electromechanical switch and the semiconductor switch can be connected to one another in series in a load path, and both are connected to the control device for switching on and off. The method can include sending a switch-off signal to the electromechanical switch at a first point in time, and sending a switch-off signal to the semiconductor switch at a second point in time that is delayed relative to the first point in time by a predetermined switch-off delay.

The control device can send a respective switch-on signal simultaneously to the electromechanical switch and to the semiconductor switch when switching on the electromechanical switch and the semiconductor switch.

Further examples of this method arise in analogy to the above-described examples of the arrangement according to the invention. Very especially preferably, these methods are used for a failure insertion unit.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows an arrangement having an electromechanical switch, a semiconductor switch, and a control device, in a failure insertion unit, according to an example of the invention,

FIG. 2 shows the control of the electromechanical switch and of the semiconductor switch during switch-on and the switch-on responses of the electromechanical switch and of the semiconductor switch according to the example of the invention,

FIG. 3 shows the control of the electromechanical switch and of the semiconductor switch during switch-off and the switch-off responses of the electromechanical switch and of the semiconductor switch according to the example of the invention, and

FIG. 4 schematically shows an arrangement according to an example of the invention, having a multiplicity of electromechanical switches, a semiconductor switch, and a control device.

### DETAILED DESCRIPTION

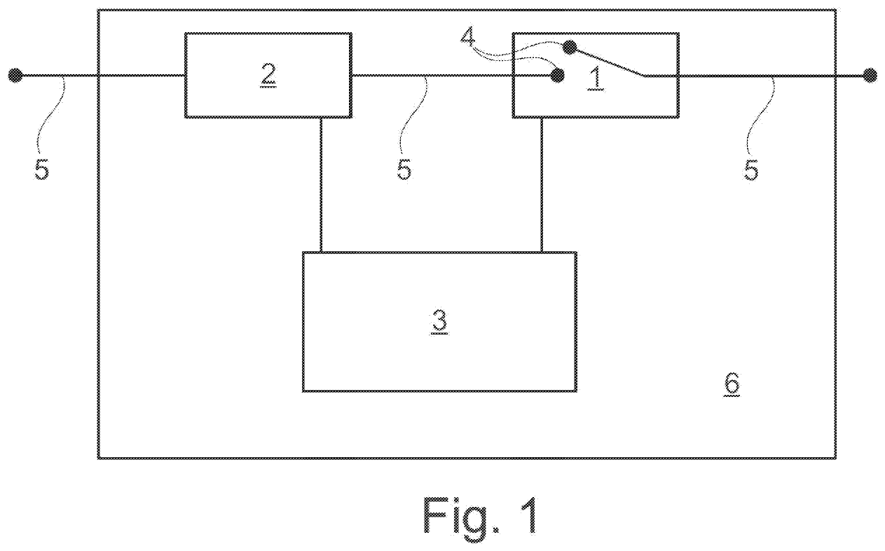

An arrangement according to an example of the invention having an electromechanical switch 1 in the form of a relay, a semiconductor switch 2 designed as a MOSFET switch, and a control device 3 can be seen schematically in FIG. 1. Both the electromechanical switch 1 and the semiconductor switch 2 can be switched on and off in each case, wherein the electromechanical switch 1 and the semiconductor switch 2 are each closed in the switched-on state and are each open in the switched-off state. The electromechanical switch 1 has switching contacts 4 that can be electromechanically connected to one another and that make contact with or are disconnected from one another for switching the electromechanical switch 1 on and off in order to establish or break a galvanically conductive connection in this way.

The electromechanical switch 1 used in the present case has neither a structural design nor a function for suppressing arcs. The electromechanical switch 1 and the semiconductor switch 2 are connected to one another in series in a load path 5. In addition, the electromechanical switch 1 and the semiconductor switch 2 are connected to the control device 3 so that the electromechanical switch 1 and the semiconductor switch 2 can be controlled by the control device 3 for switching on and off.

Here, an example is depicted in which the arrangement having the electromechanical switch 1, the semiconductor switch 2, and the control device 3 is a component part of a failure insertion unit 6. The failure insertion unit 6 is intended for connection to an HIL simulator, namely through the load path 5. The failure insertion unit 6 serves to emulate electrical failures, which are transmitted from it to the HIL simulator through the load path 6. The failure insertion unit 6 used here can, among other things, generate the following electrical failures and output them to the HIL simulator: a short circuit of a control unit output to ground potential, a short circuit of a control unit output to supply potential, a short circuit of a control unit output having a first signal line to a second signal line, and a breaking of a signal line that electrically connects a control unit output to a signal sink or connects a control unit input to a signal source.

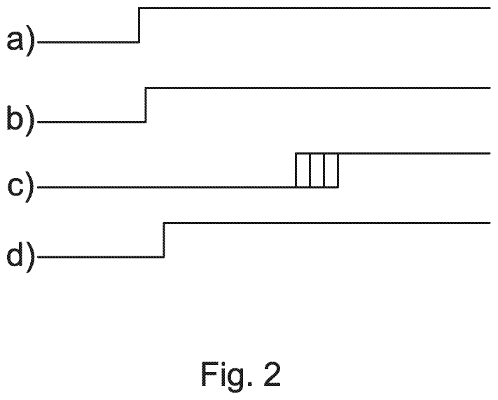

As can be seen schematically in FIG. 2, which shows the control of the electromechanical switch 1 and of the semiconductor switch 2 during switch-on as well as the switch-on responses of the electromechanical switch 1 and of the semiconductor switch 2, a respective switch-on signal is sent by the control device 3 simultaneously to the electromechanical switch 1 and to the semiconductor switch 2 (switching curves a and b) when switching on the electromechanical switch 1 and the semiconductor switch 2. However, this leads neither to an immediate switching on of the electromechanical switch 1 and of the semiconductor switch 2 nor to the electromechanical switch 1 and the semiconductor switch 2 closing at the same time. Instead, the semiconductor switch 2 has a very short response time of approximately 10 μs whereas the response time of the electromechanical switch 1 is in the range between 1 and 6 ms. Thus, the electromechanical switch 1 (switch-on curve c) closes significantly later than the semiconductor switch 2 (switch-on curve d).

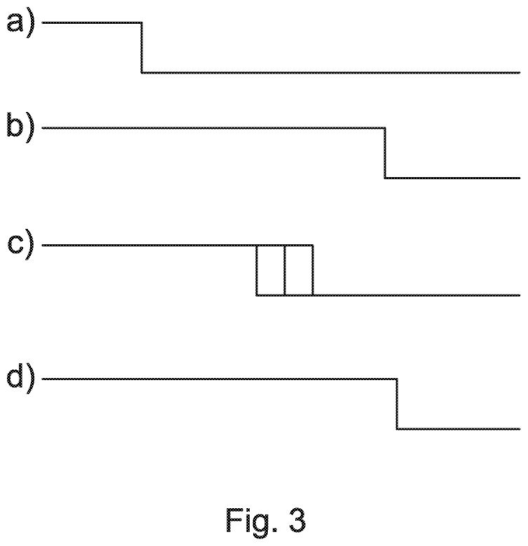

An essential aspect of the example of the invention described in the present case is that, as depicted schematically in FIG. 3, when switching off the electromechanical switch 1 and the semiconductor switch 2 in order to open the load path 5, the control device 3 first sends a switch-off signal to the electromechanical switch 1 (switching curve a), and only after that, namely after a predetermined switch-off delay, sends a switch-off signal to the semiconductor switch 2 (switching curve b). In this case, the switch-off delay is chosen such that it leads to a time-limited arc between the switching contacts 4 of the electromechanical switch 1. It must be taken into account here that the electromechanical switch 1 has an intrinsic, which is to say unavoidable, switching time for switch-off that is defined by the period between the receiving of the switch-off signal from the control device 3 and the opening of the electromechanical switch 1. This is why the procedure followed in the present case is that the switch-off delay for switching off the semiconductor switch 2 is chosen to be greater than the intrinsic switching time of the electromechanical switch 1. The electromechanical switch 1 (switch-off curve c) thus opens earlier than the semiconductor switch 2 (switch-off curve d) so that the switching contacts 4 of the electromechanical switch 1 are disconnected from one another for a certain time while the semiconductor switch 2 is still closed. In the example described here, therefore, an arc is formed between the switching contacts 4 of the electromechanical switch 1 for a period of 7 ms at most.

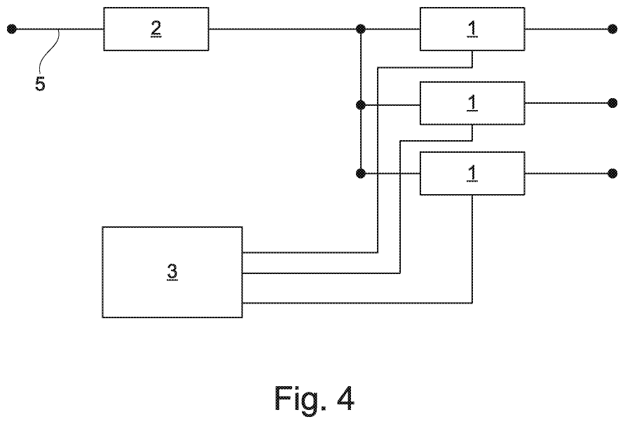

Finally, an arrangement according to an example of the invention, having a multiplicity of electromechanical switches 1, a semiconductor switch 2, and a control device 3, can be seen schematically in FIG. 4. The semiconductor switch 2 is connected to the control device 3 through a semiconductor control line, which is not shown in FIG. 4. As depicted, the semiconductor switch 2 is connected in series ahead of a multiplicity of electromechanical switches 1 that are connected in parallel with one another, all of which are connected to the control device 3 for switch-on and switch-off. In this case, the control device 3 is set such that only one of the electromechanical switches 1 can be switched on at the same time. Otherwise, the function for the individual electromechanical switches 1 is as explained above with reference to FIGS. 1, 2, and 3.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An arrangement comprising:
an electromechanical switch;
a semiconductor switch; and
a controller,
wherein the electromechanical switch and the semiconductor switch are adapted to be switched on and off,
wherein the electromechanical switch and the semiconductor switch are each closed in the switched-on state and are each open in the switched-off state,
wherein the electromechanical switch has switching contacts that are adapted to be electromechanically connected to one another for switching on and off,
wherein the electromechanical switch and the semiconductor switch are connected to one another in series in a load path, and electromechanical switch and the semiconductor switch are connected to the controller for switching on and off, and
wherein the controller is configured such that, when switching off the electromechanical switch and the semiconductor switch to open the load path, it first sends a switch-off signal to the electromechanical switch and then, after a predetermined switch-off delay, sends a switch-off signal to the semiconductor switch.

2. The arrangement according to claim 1, wherein the switch-off delay is chosen such that it leads to a time-limited arc between the switching contacts of the electromechanical switch.

3. The arrangement according to claim 2, wherein the switch-off delay is chosen such that the arc is formed between the switching contacts of the electromechanical switch for a period of 7 ms at most.

4. The arrangement according to claim 1, wherein the electromechanical switch has an intrinsic switching time for switching off that is defined by the period between the receiving of the switch-off signal from the controller and the opening of the electromechanical switch, and the switch-off delay is greater than the intrinsic switching time of the electromechanical switch.

5. The arrangement according to claim 1, wherein the electromechanical switch has neither a structural design nor a function for suppressing arcs.

6. The arrangement according to claim 1, wherein the controller is configured such that it sends a respective switch-on signal simultaneously to the electromechanical switch and to the semiconductor switch when switching on the electromechanical switch and the semiconductor switch.

7. The arrangement according to claim 1, wherein the semiconductor switch is a MOSFET switch.

8. The arrangement according to claim 1, wherein the electromechanical switch is a relay or a contactor.

9. The arrangement according to claim 1, wherein the semiconductor switch is connected in series ahead of a multiplicity of electromechanical switches that are connected in parallel with one another, all of which are connected to the controller for switch-on and switch-off, and wherein the controller is configured such that only one of the electromechanical switches is adapted to be switched on at the same time.

10. A failure insertion unit for connection to an HIL (Hardware In the Loop) simulator through a load path and for emulation of at least one electrical failure and transmission of the same to the HIL simulator through the load pat, wherein the load path comprises the arrangement according to claim 1.

11. The failure insertion unit according to claim 10, wherein the electrical failure is chosen from the group comprising: a short circuit of a control unit output to ground potential, a short circuit of a control unit output to supply potential, a short circuit of a control unit output having a first signal line to a second signal line, and/or a breaking of a signal line that electrically connects a control unit output to a signal sink or connects a control unit input to a signal source.

12. A method for controlling an electromechanical switch and a semiconductor switch, the method comprising:
electromechanically connecting switching contacts of the electromechanical switch to one another for switching on and off;
connecting the electromechanical switch and the semiconductor switch to one another in series in a load path and connecting the electromechanical switch and the semiconductor switch selectively to the control device for switching on and off;
sending a switch-off signal to the electromechanical switch at a first point in time; and
sending a switch-off signal to the semiconductor switch at a second point in time that is delayed relative to the first point in time by a predetermined switch-off delay.

13. The method according to claim 12, wherein the control device sends a respective switch-on signal simultaneously to the electromechanical switch and to the semiconductor switch when switching on the electromechanical switch and the semiconductor switch.

14. The method according to claim 12, wherein the method is configured for a failure insertion unit.
